(19) United States
(12) Patent Application Publication
(10) Pub. No.: US 2007/0203860 A1
(43) Pub. Date: Aug. 30, 2007

(54) ENERGY BUDGET MANAGER

(75) Inventors: Brian Golden, Great Falls, VA (US); Courtney McMahan, Arlington, VA (US)

Correspondence Address: BANNER & WITCOFF, LTD., 1100 13th STREET, N.W., SUITE 1200, WASHINGTON, DC, 20005-4051, US

(73) Assignee: GRIDPOINT, INC., Washington, DC (US)

(21) Appl. No.: 11/276,337

(22) Filed: Feb. 24, 2006

(51) Int. Cl. G01R 21/133

(52) U.S. Cl. 705/412

(57) ABSTRACT

A method of monitoring energy consumption includes steps of establishing an energy budget for a future time period, receiving device information for a plurality of electrical devices and associating the device information with the energy budget, periodically measuring electrical usage from the plurality of electrical devices, projecting future energy consumption for the future time period based on the measured electrical usage, comparing the projected future energy consumption to the energy budget, and if the projected future energy consumption deviates from the energy budget, automatically generating an alert. The projected future energy consumption can take into account various factors such as energy available from non-grid sources; weather forecasts; battery storage; and historical data. A system employing the method can automatically control devices to bring predicted consumption within the budget.

### BACKGROUND

The present invention relates generally to energy management, and more particularly to forecasting and budgeting of energy consumption.

Energy consumption in homes and businesses can vary widely based on weather and other factors, leading to unpredictable energy bills (including electricity, natural gas, oil, etc.). Some utilities permit customers to pay an average amount each month based on a historical average for that customer. For example, if over the course of a year a customer's electric usage varies widely, some utilities compute the average amount of electricity used per month and bill the customer each month based on that average. The average may be adjusted over time.

The aforementioned averaging scheme does nothing to help electricity purchasers reduce their demand for electricity, and the purchasers often cannot predict what their total electric bill will be until after they receive bills over time. If a customer knows that the weather has been very cold and is predicted to be cold for the rest of the month, he or she can surmise that the electrical bill for that month may be higher than normal (which may lead to an increase in the average), but it may be difficult to quantify the extent of the increase. Consequently, a customer who has a particular budget is left with little information to help budget electricity for the rest of the month or year.

Recently, devices have been developed that help users reduce electricity purchases from the power grid by storing electricity in batteries, which are then drawn down during peak hours to reduce demand from the grid. The batteries can be charged during non-peak hours, thus reducing the total cost of electricity, and electricity can be sold back to the grid during favorable conductions. Some of these devices can produce energy from secondary sources such as solar panels, fuel cells, and other sources. Such devices, such as one described in U.S. patent application Ser. No. 11/144,834 filed on Jun. 6, 2005 (entitled Optimized Energy Management System), can also reschedule deferrable electrical consumption to off-peak hours. For example, a dishwasher can be automatically scheduled to turn on during off-peak hours.

It would be desirable to help energy consumers better manage and predict their electricity consumption. The present invention provides some of these advantages.

### SUMMARY OF THE INVENTION

Variations of the invention provide a web-accessible computer tool that allows consumers of electricity to budget, view, and monitor their projected electricity usage for a particular time period (e.g., month or year). In one variation, a customer can establish an energy budget for a particular month. The tool monitors energy usage, and predicts future energy usage and costs based on variables such as weather forecasts, stored energy capacity or other local production capacity (e.g., solar cells). The projected cost of the predicted electricity usage is compared to the energy budget and, if a deviation from the budget is likely, an alert is generated. The alert can be provided via email, web page, mobile device, or other means.

In some embodiments, an alert includes recommendations for reducing energy usage to stay within the original budget. For example, an alert may recommend decreasing the thermostat in the user's home by 5 degrees, which might translate into a projected cost savings sufficient to bring the projection back within the budget.

In certain embodiments, usage can be monitored at various devices in the customer's premises (e.g., HVAC system, dryer, dishwasher, etc.) and the contribution of each device to the total budget is calculated. Passive transducers can be used to monitor and report energy usage over time.

In some embodiments, a system incorporating the invention can transmit commands to devices at the customer's premises to turn them on, off, or reduce the settings (e.g., a thermostat). The commands can be constrained by previously-established user inputs, such that a user can prevent the system from reducing the thermostat beyond a certain point if a certain mode has been selected. The system may interact with an energy management device located at the customer's premises in order to coordinate the purchase, sell-back, and usage of energy. Other features, advantages, and embodiments are described in more detail below.

### BRIEF DESCRIPTION OF THE DRAWINGS

FIG. 1 shows a system incorporating certain aspects of one embodiment of the invention.

FIG. 2 shows a method containing steps that can be carried out in accordance with certain variations of the invention.

FIG. 3 shows a computer screen that can be used to configure appliances.

FIG. 4 shows a computer screen that can be used to input electrical rates and historical usage information.

FIG. 5 shows a computer screen that can be used to input an energy budget and alert information.

FIG. 6 shows details of a monitoring/reporting loop corresponding to step 207 of FIG. 2.

FIG. 7 shows an energy “dashboard” that can be used to show a user current status and statistics relating to energy usage.

### DETAILED DESCRIPTION

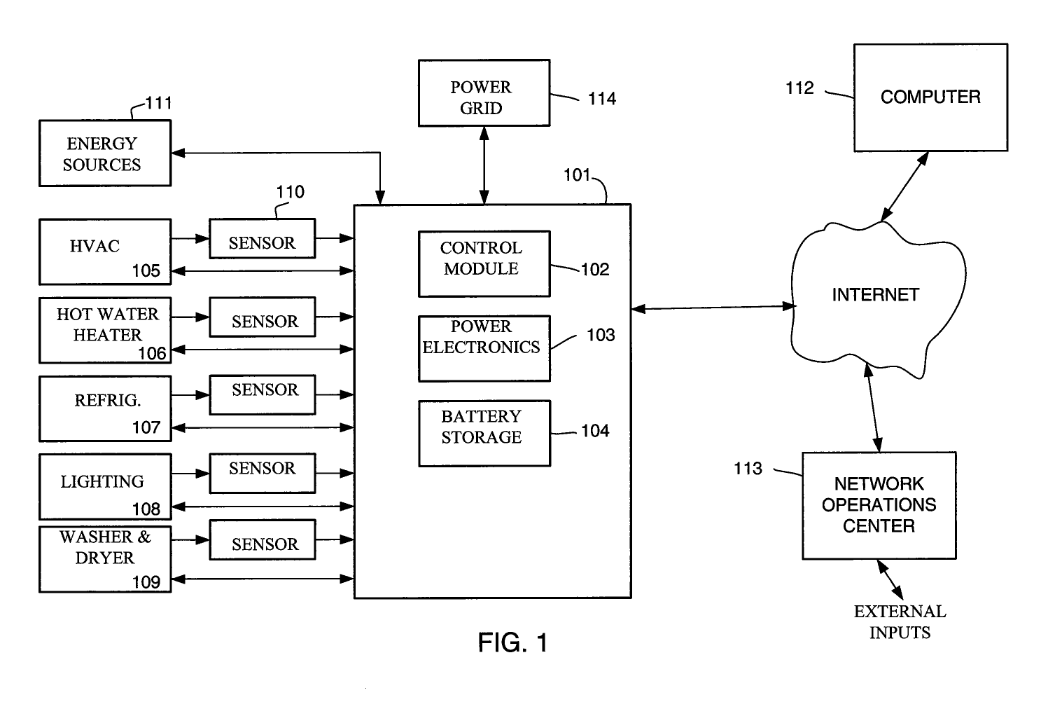

FIG. 1 shows a system incorporating certain aspects of one variation of the invention. An energy management device 101 may be located at a customer's premises and may be coupled to the power grid 114 and one or more alternative energy sources 111 (e.g., solar panels, wind turbine, fuel cell, electrical generator, etc.). The energy management device 101 may comprise various components such as a control module 102, power electronics 103, and battery storage 104. In one variation, the energy management device may be of a type described in U.S. application serial number U.S. patent application Ser. No. 11/144,834 filed on Jun. 6, 2005 (entitled Optimized Energy Management System), hereby incorporated by reference, but the particular design of the device is not critical to the present invention. Commercially available units such as GridPoint CONNECT™ or GridPoint PROTECT™, available from GridPoint Inc., of Washington D.C. can be used for device 101.

Energy management device 101 controls the consumption of electrical power at the premises (e.g., customer's home or business location), and may also control the generation and storage of electrical energy. For example, device 101 may cause energy to be purchased from the power grid during off-peak hours and stored in battery storage 104, then tap into that energy during peak electrical demand periods to efficiently allocate energy usage over time and reduce overall electrical costs.

According to one variation of the present invention, device 101 is coupled to various energy-consuming devices such as HVAC 105, hot water heater 106, refrigerator 107, lighting circuits 108, and washer/dryer 109. Other devices are of course possible and these examples are not intended to be limiting. A plurality of sensors 110 can be coupled to one or more of the energy-consuming devices to measure and report power consumption to device 101. In some embodiments, sensors can be embedded in the appliances themselves, such that each appliance self-reports its measurements.

Each sensor may be a passive type device that fits over a power cord or input line to the device, or it may be connected “in circuit” with each device to measure power consumption in units of, for example, kilowatts or volt-amperes. (Energy is power accumulated over time, such as kilowatt-hours, where one kilowatt-hour corresponds to the amount of energy consumed by one kilowatt expended continuously over one hour). Each sensor reports the measured power consumption, which may vary over time, to device 101, which records the measurements for each device. Each sensor may report measurements by wired or wireless means. Measurements may be sampled at any suitable or desired interval, such as every 0.10 seconds.

Any of various types of sensors may be used. For example, separate voltage and amperage sensors may be used to measure voltage and amperage at regular intervals. Alternatively, a kilowatt-hour meter or other type of sensor may be used. The sensors may be analog or digital, and may be single-phase or multi-phase.

Device 101 is in turn coupled via a network such as the Internet to a network operations center (NOC) 113, and transmits measured power usage to NOC 113 periodically. One or more computers 112 may also be coupled via the Internet or other means (e.g., direct connection to device 101) to perform configuration and monitoring as described in more detail below. The computer may be located at the customer's premises or at another location. Additionally, the NOC 113 can be located at the customer's premises or a remote location.

Energy management device 101 may be optional in certain variations of the invention, and electrical usage from the premises (preferably, from individual appliances) can be measured and reported to a center such as network operations center 113 as described further below. For example, measurements from the sensors may be collected by a computer 112, which reports them to NOC 113 via the Internet. In other embodiments, each sensor may include an Internet connection circuit that allows measurements to be reported directly over the Internet or other means (e.g., WiFi) to NOC 113. In yet other embodiments, measurements are reported locally (e.g., to a computer such as computer 112 or device 101) and projections are calculated and reported locally, without involving an external NOC 113.

NOC 113 may receive one or more parameters via external inputs such as via the Internet, via manual entry, or other means. Such parameters may include, but are not limited to: weather forecasts for the location corresponding to the customer's premises; electricity rate schedules corresponding to each customer's premises (e.g., electrical rates as a function of time); prevailing and/or projected fuel costs; typical energy usage for a home of a given size; typical energy usage for various types of appliances; and others.

In one variation of the invention, NOC 113 permits a customer to create an account; set one or more energy budgets; monitor and display energy consumption; predict energy usage and associated costs, and generate alerts if a given energy budget is projected to be exceeded or incur some other deviation.

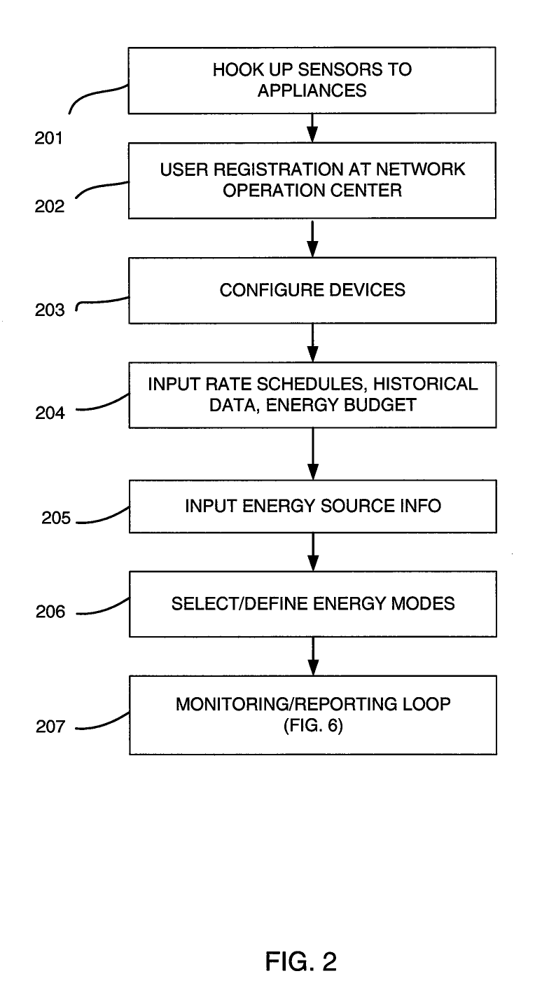

FIG. 2 shows method steps, some of which may be optional, that can be carried out in accordance with the invention. Beginning in step 201, sensors are connected to appliances in a customer's premises (e.g., a home). For example, a passive sensor can be coupled to the power line leading to a hot-water heater 106, which periodically measures the power consumed by the hot-water heater and reports the measurement to device 101, or to a computer 112, or to NOC 113 via Internet or other wireless means. As another example, an in-circuit sensor can be coupled to one or more lighting circuits 108, which periodically measures the power consumed by each lighting circuit and reports the measurements as described above. Although not shown in FIG. 1, device 101 may also periodically report the remaining charge on batteries 104, and the available or projected energy available from alternative energy sources 111 (e.g., solar cells) to NOC 113, such that NOC 113 can display these values on computer 112 along with other pertinent information. For example, a user could log in from the office to obtain a report regarding the available energy storage at the user's home.

In step 202, the user registers at the NOC 113 to create an account. This can include conventional steps of creating a user name and password, and collecting account information such as the serial number of energy management device 101 (if one is available), billing address, geographic location of premises (e.g., zip code), e-mail address or SMS addresses for notifications, etc. The registration step can be performed via the Internet using a computer 112. Alternatively, the registration can be performed locally at device 101, such that the steps and processes described in more detail below are performed entirely at the premises.

In step 203, the device configuration for the user's premises is obtained. For each appliance having a corresponding sensor, the user can supply the make and model of the appliance (if known) and correlate that appliance with a sensor serial number and/or device name (e.g., downstairs washing machine). This creates a database of sensors and corresponding appliances. Optionally, the communication protocol used by each sensor (e.g., TCP/IP, serial bus, etc.) can be specified.

In some embodiments, each appliance can be identified as deferrable, critical, or rate-controlled. For example, a refrigerator can be identified as critical, meaning that power to that device will not be turned off during a power-saving period, whereas a hot-water heater could be identified as deferrable, meaning that power to the device could be turned off in order to save power. As another example, the thermostat controlling the HVAC could be identified as rate-controlled, meaning that a range of consumption would be permitted based on a power-saving mode (e.g., turn down the temperature by up to 20 degrees for power-saving mode; by up to 10 degrees for standard mode; and by up to 5 degrees for comfort mode). Other modes and options are possible.

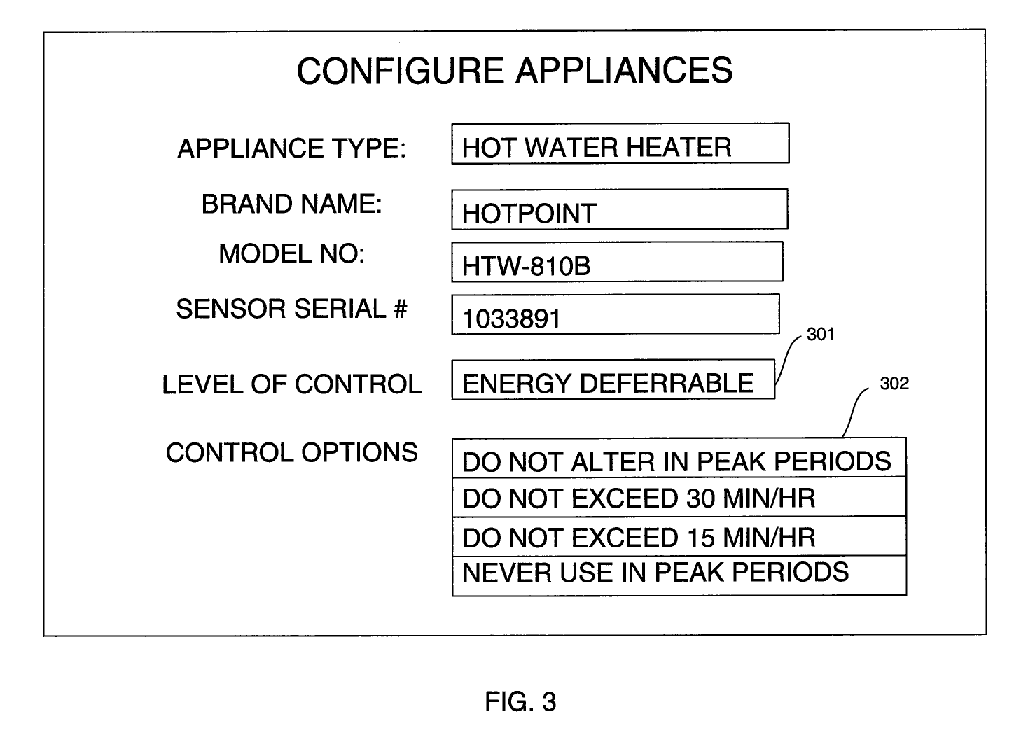

Turning briefly to FIG. 3, an example is shown of a computer input screen that can be used to collect information of the type described with reference to step 203. The information can be obtained via drop-down menus, fill-in-the-blank fields, radio dial buttons, and/or other means. FIG. 3 also shows energy-deferral information 301 and 302. Information is collected for each appliance located at the premises for which measurements will be taken or for which energy usage will be estimated. If a device does not have an associated sensor, an estimate of energy usage can be made by the NOC 113 based on the device type and other parameters (e.g., geographic location of the appliance and number of household members using the device). Although not shown in FIG. 3, additional screens can be provided to obtain information regarding energy storage of batteries in device 101 and/or production capacity of energy-producing devices located at the premises (e.g., solar panels). This information could also be obtained directly from device 101 if it is already known, as could some of the other information identified above.

In one embodiment, NOC 113 contains a database of devices and associated estimated energy consumption and costs of operation. This data can be derived, for example, from the U.S. Government's ENERGY STAR program or from third-party databases. For example, once the customer identifies a particular dishwasher make and model, the projected power or energy consumption for that appliance can be retrieved from a database stored at NOC 113 and used to estimate consumption. Estimated energy consumption can be based on the number of people using the device (e.g., a family of four for a water heater or dryer) and on other factors. As actual consumption is measured by sensors 110 and transmitted to NOC 113 over time, the original estimates can be replaced by more accurate actual usage from the customer's premises.

Returning to FIG. 2, in step 204, the user can input electrical rate schedules (e.g., cost per kilowatt hour for peak and off-peak usage). Additionally, historical information regarding electrical consumption can be collected to use as a baseline. For example, the user can supply his or her actual electrical energy usage and cost for each of the previous 12 months, and the NOC 113 can store this information and correlate it with other data such as the historical average temperature for each of those months. This can provide a baseline against which a future month can be gauged based on predicted weather. If the customer's electrical rates are known, they can also be entered during this phase. (Alternatively, they can be automatically retrieved from a database based on the name of the electric utility and/or the geographic location of the premises). Finally, the user can input the square footage of the premises, and other factors such as what type of insulation is used in the attic. This data can be used to help project the average cost of energy for a baseline period using any of various models.

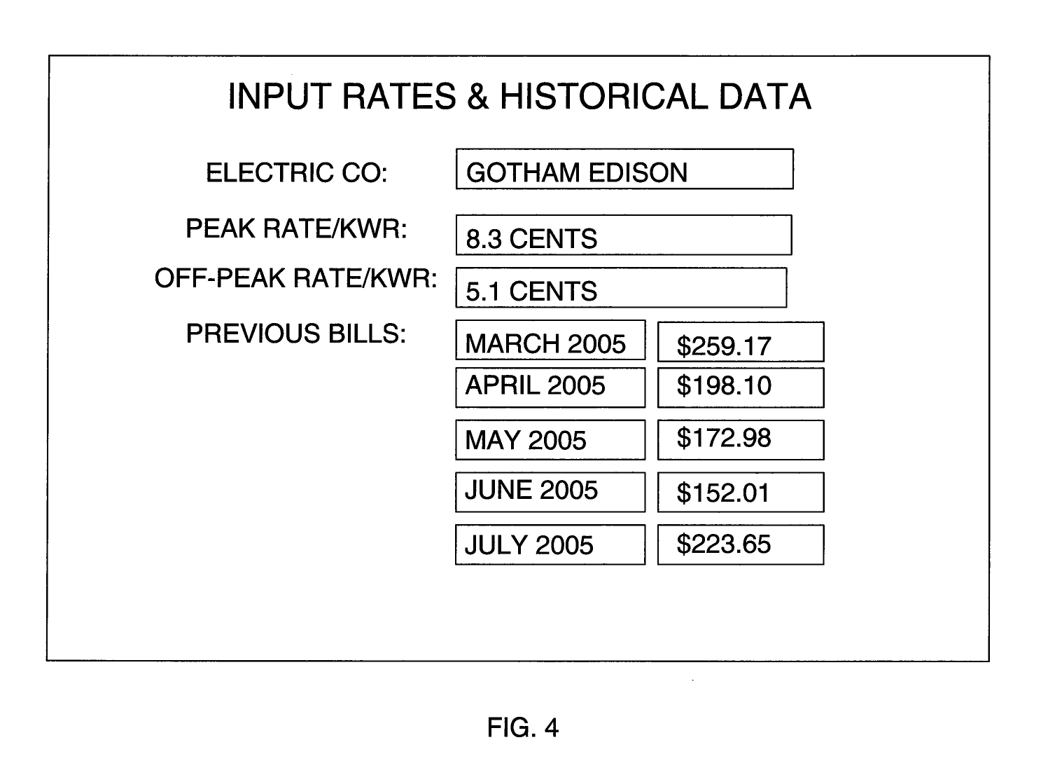

FIG. 4 shows one possible computer screen that can be used to input electrical rates and historical electric usage data. As shown in FIG. 4, the consumer can input the utility name and/or peak and off-peak electrical rates. These can alternatively be retrieved from a database based on the consumer's zip code, for example. The consumer can also provide historical usage data based on previous utility bills. Alternatively, this data could be downloaded from the utility based on the user's account number (not shown) or other data.

Also in step 204, the user can input an energy budget for each of a plurality of months. The budget can be established as a dollar amount or in energy usage (e.g., KWH). In one embodiment, a computer program in NOC 113 calculates a proposed energy budget that is a fixed percentage lower—e.g., 10%—than the user's historical averages. Thus, for example, if the user's actual electric bill for the month of March for the previous year was $200, NOC 113 could propose an electrical energy budget of $180 for the month. Additionally, the user can provide an email address, telephone number, or other contact information that will be used to alert the user if the projected energy budget will be exceeded.

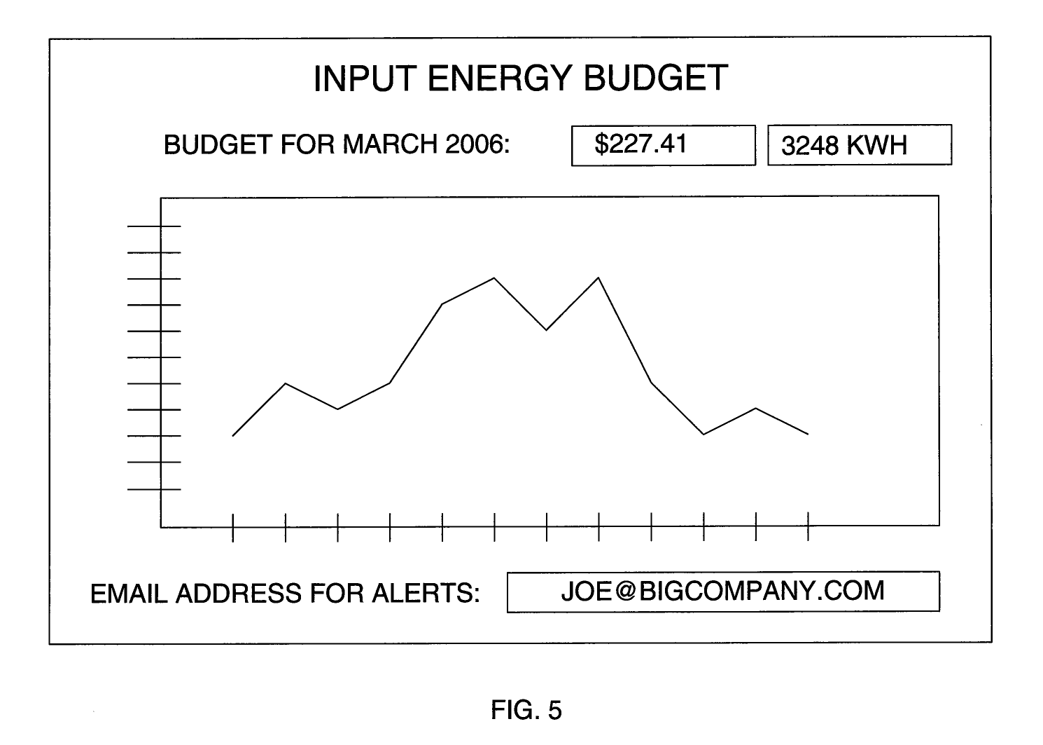

FIG. 5 shows one possible computer screen that can be used to input an energy budget. The information can be provided manually by the consumer, or it can be derived based on historical data (e.g., establishing an energy budget that is 10% less than the actually used energy for the same month in the prior year).

Returning to FIG. 2, in step 205 information regarding available energy sources can be optionally provided. For example, if the location includes a solar panel, information regarding the capacity of the panel can be provided. Information regarding the storage capacity of batteries in unit 101 can also be provided if not already established. This data can be used to help predict whether projected demand can be satisfied without relying on the electrical grid, and thus potentially reducing the cost of the supplied electricity. For example, if the user has a solar panel that can supply 800 kilowatts of electricity during peak hours in full sunshine, that fact can be used to reduce the projected purchase of electricity from the grid for a particular day.

In step 206, the user can optionally define one or more energy modes for the premises and can specify what mode should be used for particular time periods. For example, one mode can be defined as a HIGH SECURITY mode. In that mode, the customer can specify which devices should not be turned off to save electrical energy. Additionally, selling power back to the grid can be inhibited, and the batteries would remain fully charged at all times. A CONSERVATION mode can be defined to permit shut-off of specified appliances when needed to reach a given energy budget. This mode could include, for example, an aggressive thermostat setting that permits the thermostat to be reduced up to 15 degrees if necessary to save energy and thus remain within budget. A COMFORT mode can be defined to permit shut-off of deferrable loads but that permits the thermostat to be reduced by no more than 5 degrees to save energy. A VACATION mode could shut off all devices except for a minimal amount of heat necessary to keep pipes from freezing. Various other user-configured modes can be provided as desired, each with one or more parameters that specify how appliances can be controlled in order to achieve a given energy budget.

These modes can be used independently of or used in conjunction with the control options shown in FIG. 3. For example, if in FIG. 3 the user specifies that the default control level for a hot-water heater is “Do not exceed 30 minutes/hour” for energy deferral, but the user selects the HIGH SECURITY mode, energy deferral for the hot-water heater would be overridden and the default control levels ignored.

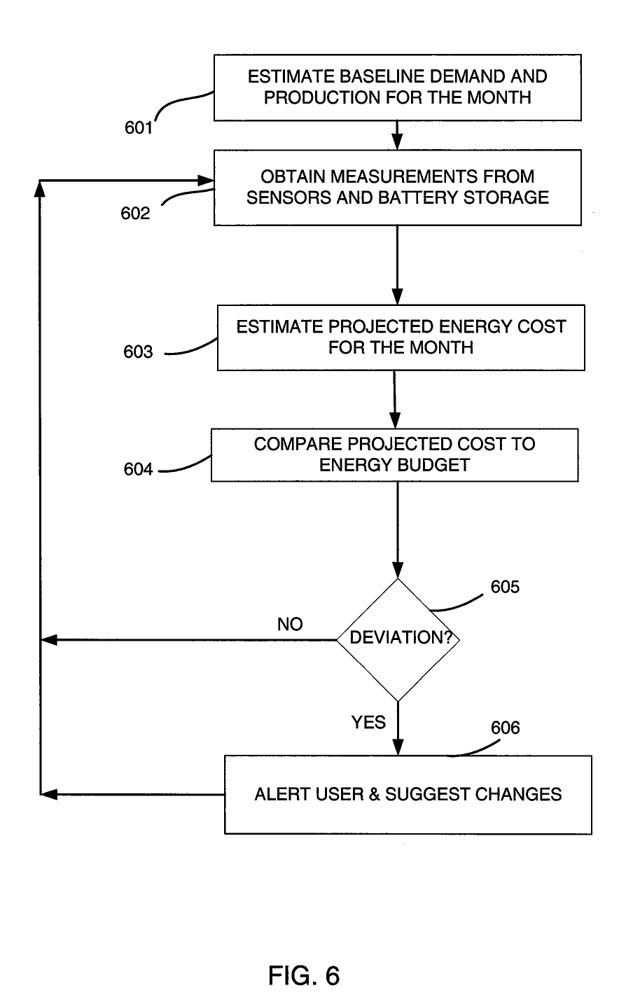

In step 207, an energy monitoring/reporting loop is performed, with calculations and alerts generated as described in more detail below with respect to FIG. 6.

FIG. 6 shows details of a monitoring/reporting loop that can be carried out according to various aspects of the invention.

Beginning in step 601, it is assumed that the user has established an energy budget for a given month as described above. It is also assumed that the first time the process is carried out, there are no actual measurements from the sensors on which to base projections of energy usage. Consequently, in step 601a baseline estimate of the projected electrical energy demand for the month and the estimated production from non-grid sources (e.g., solar panels, batteries, etc.) is calculated. Examples of calculating some of these values are provided in previously-filed U.S. application Ser. No. 1/144,834 filed on Jun. 6, 2005 (entitled Optimized Energy Management System). Other approaches, such as those described below, can also be used.

The baseline estimate of projected energy demand for the month can be determined as follows. Other ways of estimating the projected energy usage are of course possible. One simple way of estimating energy usage for the month is to rely on historical data. Thus, if during the month of May 2005 the user used 2410 KWH of electricity, it can be estimated that for May 2006 the same demand would be required, adjusting the corresponding cost if necessary for changes in utility rates or other parameters. The estimate can be adjusted in other ways to arrive at a more accurate number. For example, if based on weather forecasts the month of May 2006 is projected to be quite a bit hotter than May 2005 was, the projected demand can be increased.

A database can be provided incorporating historical correlations between temperature variations and projected energy usage. For example, for every degree of temperature variation above a given outdoor temperature, it could be estimated that heating/air conditioning energy usage for a given day would be 3% higher than the given temperature. If historical data shows that energy usage for HVAC on a 70-degree day amounted to 20 KWH, then the projection for a 72-degree day could be estimated to incur energy usage of 21.2 KWH. Alternatively, a database of solar insolation values can be provided based on the geographic area in which the energy usage is incurred, and this database can be used to estimate energy usage.

The demand can be allocated to individual days in the month, e.g., by dividing the projected demand for the month by the number of days in the month. If actual usage data is available on a day-by-day basis, that information can instead be used.

The estimated demand can also be adjusted based on the energy mode selected by the user. For example, if CONSERVATION mode has been selected, and the historical data for the month (before the equipment was installed) showed actual usage of 2410 KWH of electricity, it can be deduced that CONSERVATION mode would save approximately 10% of that month's electricity demand, and the demand estimate could be lowered accordingly. The ENERGY STAR database can be used to provide profiles, for example, of water heater usage. Additionally, each energy-consuming device could be configured based on the mode (e.g., a water heater might use an average of 400 KWH for a typical day, but if placed in a mode in which it is only activated for 8 hours a day, it might only use 200 KWH.).

The baseline energy supply for the month can also be estimated. Of course, energy from the power grid is essentially unlimited. To the extent that alternative sources are available (e.g., solar panels, battery storage, etc.), an estimate can be made for each day regarding the available supply from those sources, which would decrease the amount of energy that would need to be purchased from the grid. For example, if an 800-watt solar panel is available and the average weather forecast for the month of May is sunny with long periods of sunshine, the output of the solar panel can be included in the energy supply, and deferrable loads can be scheduled to operate during periods of “free” solar energy.

In step 602, measurements from the sensors (and battery capacity, if available) are obtained and stored. For electrical loads, measurements can be sampled every tenth of a second. For batteries, measurements can be sampled every 15 minutes. These sampling rates can be changed and are not critical. If electrical power is measured, measurements can be integrated over time in order to obtain electrical energy. If electrical energy is measured (e.g., using a KWH meter), energy measurements can be obtained. Measurements can be stored locally in device 101 and then (e.g., overnight) transmitted to NOC 113. Alternatively, measurements can be transmitted periodically during the day, or after each measurement.

In step 603, the total projected energy cost for the month is calculated. This can be done by various methods. One approach is to assume that the next day's energy consumption will be the same as the previous day's measured consumption, adjusted for weekday schedules (e.g., treating weekdays differently than weekends), and for weather (i.e., a predicted 20% higher-than-normal outdoor temperature would lead to a similar increase in electrical consumption for HVAC systems). Another approach is to calculate, for each day of the month, projected demand and projected on-site supply during peak and off-peak hours, and the remainder represents what must be purchased from the grid (i.e., energy cost). The following relations show one possible approach to arrive at the projected cost:
Projected Cost for Month=Projected Costs to Date+Projected Future Costs
Projected Costs to Date=SUM(Peak Rate×Measured KWHₚₑₐₖ+Off-Peak Rate×Measured KHW_{off-peak}) across all days of the month that have been measured.
Projected Future Costs=SUM [(Projected Demandₚₑₐₖ−Projected Supplyₚₑₐₖ)×Peak Rate+(Projected Demand_{offpeak}−Projected Supply_{off-peak})×Off-Peak Rate] across all future days of the month.

Projected Demandₚₑₐₖ=can be determined for each future day based on historical values and/or heuristics (see above). In one variation, the projected demand during peak hours for a given day can be estimated to be the same as the actual measured demand from another previous day having weather characteristics that most closely match the expected weather for the given day, adjusted to account for weekday/weekend variations. Weather forecasts may be weighted based on how far into the future they forecast.

Projected Supplyₚₑₐₖ=zero (if reliant entirely on grid) or, if alternative power sources are available, taking into account projected supply from such alternative power sources such as solar panels and batteries.

Projected Demand_{off-peak}=estimated similarly to Projected Demandₚₑₐₖ, but for off-peak hours.

Projected Supply_{off-peak}=estimated similarly to Projected Supply_{off-peak}, but for off-peak hours.

Other variations of estimating and calculating the above values can be found in the aforementioned U.S. application Ser. No. 11/144,834 filed on Jun. 6, 2005.

In step 604, the projected cost for the month is compared to the energy budget for the month. In step 605, if the projected cost is outside a limit or range established for the energy budget (e.g., the budget would be exceeded or would fall below the budget by a certain margin), an alert is generated in step 606 and (optionally) transmitted to the customer via any of various methods. Additionally, in step 606 the system may suggest changes to the customer in order to bring the projected costs back within budget. For example, if it is the middle of the month (i.e., 15 days remaining) and the budget is expected to be exceeded by $80, the system can recommend and even automatically lower the thermostat setting by 12 degrees for the remaining 15 days of the month in order to achieve the necessary $80 savings. If, however, the user had set the system to COMFORT mode which prevented reducing the thermostat by more than a certain level, the system could make the maximum thermostat reduction and suggest other changes (e.g., turning off the hot-water heater for the maximum permitted time periods).

In certain embodiments, the system can learn from changes made during a cycle. For example, if the system mode is changed from COMFORT to CONSERVATION, the system would then be able to estimate (in the future) how much energy was actually saved by such a change for a given set of variables (e.g., outside temperature, battery charge, etc.). In other words, it could extrapolate a future energy savings for such a mode change based on historical data.

If the system makes changes to the demand side (such as lowering the thermostat or cycling the hot-water heater), such changes would reduce the projected future demand for the remaining 15 days of the month, so that when the process loops back to step 603, the lowered projections would be taken into account.

The system can be programmed to incorporate hysteresis so that alerts are not alternately generated and canceled as minor changes to the projections occur. For example, in such embodiments, no change in alert status would be made unless the projected changes exceeded $10 one way or another. Furthermore, projections made near the end of the month are likely to be much more accurate than those at the beginning of the month, and each day's projection can be weighted according to where it occurs in the month.

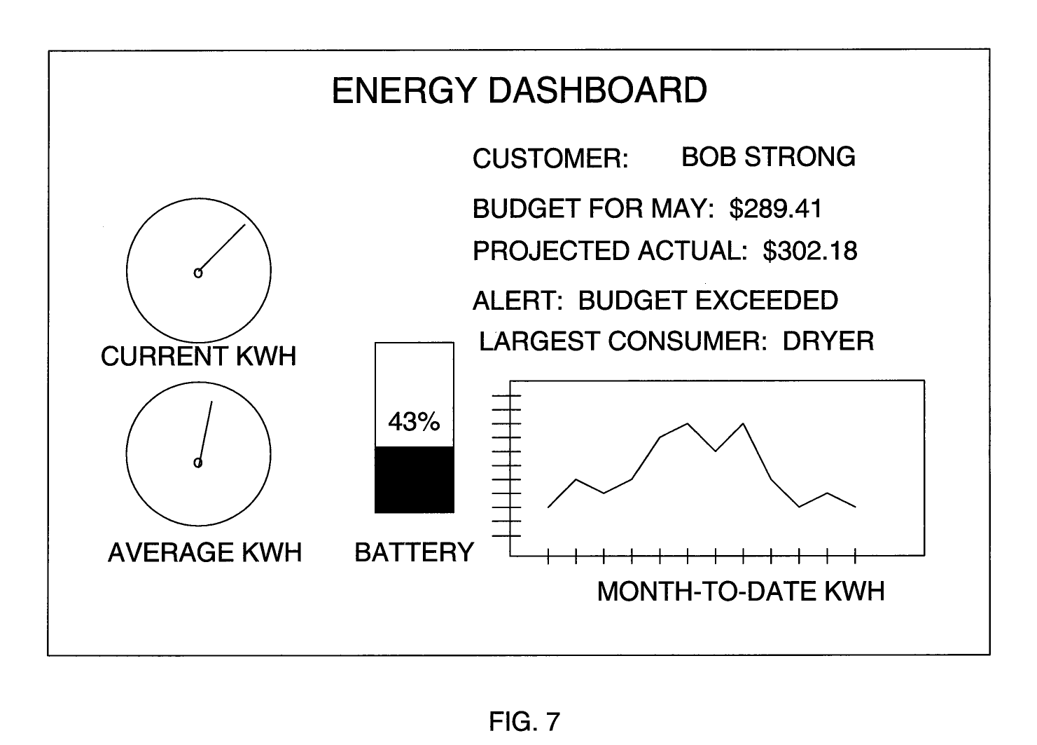

In addition to generating alerts and/or making suggestions and control changes to the user's electrical consumption, the system can display statistics and measures on a web site or locally connected computer. FIG. 7 shows an energy “dashboard” that can be used to show a user current status and statistics relating to energy usage based on measurements and projections.

In addition to estimating electricity usage as described above, in some variations of the invention the system can detect that a particular appliance is using more electricity than it is expected to consume and, based on that detection, issue an alert. If, for example, a particular model of a Frigidaire refrigerator is advertised to average 10 KW per hour, but measurements from the sensors show that it is actually consuming 15 KW per hour, an alert can be generated, prompting the consumer to call for repairs. The advertised or expected averages for each device can be stored in a database in NOC 113 and used for comparison purposes with measurements from the sensors.

Although the above steps have been described in the context of a method, a processor can be programmed with computer-executable instructions for carrying out the steps. Such a processor and associated memory and network interface is intended to be included within the scope of the invention. The invention may be implemented in software, hardware, or a combination of the two. Any of the method steps described herein can be implemented in computer software and stored on computer-readable medium for execution in a general-purpose or special-purpose computer or device (including PLDs, PGAs, etc.) and such computer-readable media is included within the scope of the intended invention. The special-purpose or general-purpose computer may comprise a network interface for communicating over a network to carry out various principles of the invention. Numbering associated with process steps in the claims is for convenience only and should not be read to require any particular ordering or sequence.

The term “electrical device” encompasses not only appliances such as water heaters and the like, but also measurement devices such as thermostats that control other devices.

The term “alert” encompasses not only audible or visual stimuli but also e-mail messages, pager messages, text messages, changes to web pages, and other forms of notification.

The term “deviates from” includes not only exceeding a value but exceeding such a value by more than a predetermined margin, falling below such a value, or falling below such a value by more than a predetermined margin.

The term “electrical usage” includes not only power consumption (e.g., kilowatts) but energy consumption (e.g., power consumption integrated over time, such as kilowatt-hours or dollars corresponding to kilowatt-hours).

The term “energy budget” may include a dollar value, power consumption, or some other value relating to an amount of energy against which measurements will be compared.

1. A computer-assisted method of managing energy consumption, comprising the steps of:
(1) establishing an energy budget for a future time period;
(2) receiving device information for a plurality of electrical devices and associating the device information with the energy budget;
(3) periodically measuring electrical usage from the plurality of electrical devices;
(4) projecting future energy consumption for the future time period based on the measured electrical usage periodically measured in step (3);
(5) comparing the projected future energy consumption to the energy budget; and
(6) if the projected future energy consumption deviates from the energy budget, automatically generating an alert.

2. The method of claim 1, wherein the electrical devices are located in a building and the projected future energy consumption and the energy budget relate only to the electrical devices located in the building.

3. The method of claim 1, further comprising the step of repeating steps (3) and (4) over the future time period and adjusting the projected future energy consumption based on the measurements in step (3).

4. The method of claim 3, wherein step (4) comprises the step of taking into account a weather forecast corresponding to the geographic location of the electrical devices.

5. The method of claim 3, wherein step (4) comprises the step of estimating local energy production available from non-grid sources at the geographic location of the electrical devices.

6. The method of claim 3, wherein step (4) comprises the step of projecting future energy costs for peak and off-peak electricity periods.

7. The method of claim 2, further comprising the step of establishing a baseline estimate of future energy consumption associated with the building based on historical data.

8. The method of claim 1, further comprising the step of generating a recommendation for reducing energy consumption by reducing demand associated with one or more of the plurality of electrical devices.

9. The method of claim 1, further comprising the step of, in response to step (6), automatically transmitting a command to one or more of the electrical devices to automatically adjust energy consumption.

10. The method of claim 9, wherein the automatically transmitted command reduces a temperature setting of a thermostat.

11. The method of claim 1, wherein step (4) comprises the step of taking into account a mode setting that inhibits reductions in energy consumption for certain modes.

12. The method of claim 1, wherein step (4) comprises the step of taking into account energy storage capacity available to power one or more of the plurality of electrical devices.

13. The method of claim 1, further comprising the steps of receiving registration information from a user associated with the plurality of electrical devices and, in response to step (6), transmitting the alert to a user-defined location.

14. The method of claim 1, further comprising the step of receiving sensor configuration information that associates a sensor used for measuring in step (4) to one of the plurality of electrical devices.

15. The method of claim 1, further comprising the step of receiving user-defined mode settings that constrain an energy-saving mode of one or more of the electrical devices and, in response to step (6), constraining the energy-saving mode.

16. The method of claim 1, further comprising the step of displaying at a network-accessible location updated electrical consumption information associated with the plurality of electrical devices.

17. The method of claim 1, wherein steps (2), (4), (5), and (6) are performed at a location remote from a building at which the electrical devices are located, and wherein the measurements in step (3) are transmitted from the building to the remote location over a network.

18. The method of claim 1, wherein steps (1) through (6) are all performed a building location at which the electrical devices are located.

19. The method of claim 1, further comprising the step of calculating the energy budget as a dollar value.

20. A computer having a memory programmed with computer-executable instructions that, when executed by the computer, perform the steps of:
(1) establishing an energy budget for a future time period;
(2) receiving device information for a plurality of electrical devices and associating the device information with the energy budget;
(3) periodically receiving measured electrical usage from the plurality of electrical devices;
(4) projecting future energy consumption for the future time period based on the measured electrical usage periodically measured in step (3);
(5) comparing the projected future energy consumption to the energy budget; and
(6) if the projected future energy consumption deviates from the energy budget, automatically generating an alert.

21. The computer of claim 20, wherein the electrical devices are located in a building and the projected future energy consumption and the energy budget relate only to the electrical devices located in the building.

22. The computer of claim 20, wherein the computer-executable instructions further perform the step of repeating steps (3) and (4) over the future time period and adjusting the projected future energy consumption based on the measurements in step (3).

23. The computer of claim 22, wherein step (4) comprises the step of taking into account a weather forecast corresponding to the geographic location of the electrical devices.

24. The computer of claim 22, wherein step (4) comprises the step of estimating local energy production available from non-grid sources at the geographic location of the electrical devices.

25. The computer of claim 22, wherein step (4) comprises the step of projecting future energy costs for peak and off-peak electricity periods.

26. The computer of claim 21, wherein the computer-executable instructions further comprise the step of establishing a baseline estimate of future energy consumption associated with the building based on historical data.

27. The computer of claim 20, wherein the computer-executable instructions further comprise the step of generating a recommendation for reducing energy consumption by reducing demand associated with one or more of the plurality of electrical devices.

28. The computer of claim 20, wherein the computer-executable instructions further comprise the step of, in response to step (6), automatically transmitting a command to one or more of the electrical devices to automatically adjust energy consumption.

29. The computer of claim 28, wherein the automatically generated command reduces a temperature setting of a thermostat.

30. The computer of claim 20, wherein step (4) comprises the step of taking into account a mode setting that inhibits reductions in energy consumption for certain modes.

31. The computer of claim 20, wherein step (4) comprises the step of taking into account energy storage capacity available to power one or more of the plurality of electrical devices.

32. The computer of claim 20, wherein the computer-executable instructions further comprise the steps of receiving registration information from a user associated with the plurality of electrical devices and, in response to step (6), transmitting the alert to a user-defined location.

33. The computer of claim 20, wherein the computer-executable instructions further comprise the step of receiving sensor configuration information that associates a sensor used for measuring in step (4) to one of the plurality of electrical devices.

34. The computer of claim 20, wherein the computer-executable instructions further comprise the step of receiving user-defined mode settings that constrain an energy-saving mode of one or more of the electrical devices and, in response to step (6), constraining the energy-saving mode.

35. The computer of claim 20, wherein the computer-executable instructions further comprise the step of displaying on a network-accessible page updated electrical consumption information associated with the plurality of electrical devices.

36. The computer of claim 20, wherein steps (2), (4), (5), and (6) are performed at a location remote from a building at which the electrical devices are located, and wherein the measurements in step (3) are transmitted from the building to the remote location over a network.

37. The computer of claim 20, wherein steps (1) through (6) are all performed a building location at which the electrical devices are located.
